(19) United States
(12) Patent Application Publication
(10) Pub. No.: US 2022/0120410 A1
(43) Pub. Date: Apr. 21, 2022

(54) LIGHT SOURCE INCLUDING EFFECTIVE REFRACTIVE INDEX CONTROLLING PATTERN

(71) Applicants: UNIVERSIT-INDUSTRY COOPERATION GROUP OF KYUNG HEE UNIVERSITY, Gyeonggi-do (KR); Hexasolution Co., Ltd., Suwon-si (KR)

(72) Inventors: Sun-Kyung Kim, Suwon-si (KR); Young Bin Kim, Yongin-si (KR); Dukkyu Bae, Yongin-si (KR); Gaeul Cho, Uiwang-si (KR)

(73) Assignees: UNIVERSITY-INDUSTRY COOPERATION GROUP OF KYUNG HEE UNIVERSITY, Gyeonggi-do (KR); Hexasolution Co., Ltd., Suwon-si (KR)

(21) Appl. No.: 17/459,519

(22) Filed: Aug. 27, 2021

(30) Foreign Application Priority Data
Oct. 16, 2020 (KR) 10-2020-0133863

(51) Int. Cl. F21V 5/04; F21V 9/30; H01L 33/06; H01L 27/15

(52) U.S. Cl. CPC F21V 5/045; F21V 9/30; F21Y 2115/10; H01L 27/156; H01L 33/06

(57) ABSTRACT

Provided is a light source. The light source includes a substrate, a light emitting layer provided on the substrate and configured to emit light, and a plurality of unit structures provided on the light emitting layer, wherein the unit structures are arranged along a radial direction and a tangential direction to form an effective refractive index controlling pattern, wherein the effective refractive index controlling pattern is configured to control the effective refractive index through a first variable defined by a width of each of the unit structures, a second variable defined as a period in which the unit structures are arranged in the tangential direction, a third variable defined as a period in which the unit structures adjacent in the radial direction are arranged, and a fourth variable defined as a difference between a refractive index of the unit structures and a refractive index of a material surrounding the unit structures, wherein the first variable is smaller than a central wavelength of the light emitted from the light emitting layer, wherein the effective refractive index controlling pattern has rotational symmetry.

### CROSS-REFERENCE TO RELATED APPLICATIONS

This U.S. non-provisional patent application claims priority under 35 U.S.C. § 119 of Korean Patent Application No. 10-2020-0133863, filed on Oct. 16, 2020, the entire contents of which are hereby incorporated by reference.

### BACKGROUND

The present disclosure herein relates to a light source including an effective refractive index controlling pattern, and more particularly, to a lens having a pattern for controlling an effective refractive index through an arrangement of unit structures, and a light source including the same.

Optical systems are an essential component of cameras, TVs, microscopes, telescopes, etc. that are part of today's advanced technology, and among them, lenses play a very important role. In general, optical lenses are basically made by combining several convex and concave lenses. At this time, light is refracted at different angles depending on the thickness of the lens and the spherical shape, so it is possible to adjust the light to focus the subject. However, the conventional optical lens has excellent optical properties because it is generally made of thick glass, but is bulky and heavy, and performs only a limited function.

In addition, optical sensors using semiconductor-based sensor arrays are increasingly used in mobile devices, wearable devices, and the Internet of Things. Although miniaturization of these devices is required, it is difficult to reduce the thickness of an optical lens included in the devices. Existing lenses that control optical performance using curvature use the principle that the phase difference of light varies according to thickness, so that the thickness of the lens must be different for each position. Accordingly, there is an attempt to implement a lens in which the length of the light traveling path is changed according to the position while being flat and thin.

### SUMMARY

The present disclosure provides a lens capable of controlling an effective refractive index through an arrangement of unit structures and adjusting directivity through this, and a light source including the same.

An embodiment of the inventive concept provides a light source including a substrate, a light emitting layer provided on the substrate and configured to emit light, and a plurality of unit structures provided on the light emitting layer. The unit structures may be arranged along a radial direction and a tangential direction to form an effective refractive index controlling pattern. The effective refractive index controlling pattern may be configured to control the effective refractive index through a first variable defined by a width of each of the unit structures, a second variable defined as a period in which the unit structures are arranged in the tangential direction, a third variable defined as a period in which the unit structures adjacent in the radial direction are arranged, and a fourth variable defined as a difference between a refractive index of the unit structures and a refractive index of a material surrounding the unit structures. The first variable may be smaller than a central wavelength of the light emitted from the light emitting layer. The effective refractive index controlling pattern may have rotational symmetry.

In an embodiment, a density of the unit structures may change in the radial direction.

In an embodiment, the density of the unit structures monotonically may increase, monotonically decrease, or increase or decrease repeatedly along the radial direction.

In an embodiment, in the effective refractive index controlling pattern, the first variable may be constant.

In an embodiment, in the effective refractive index controlling pattern, the second variable may increase along the radial direction.

In an embodiment, in the effective refractive index controlling pattern, the second variable may decrease along the radial direction.

In an embodiment, in the effective refractive index controlling pattern, the third variable may be smaller than the central wavelength of the light.

In an embodiment, in the effective refractive index controlling pattern, the first variable may decrease along the radial direction.

In an embodiment, in the effective refractive index controlling pattern, the first variable increases along the radial direction.

In an embodiment, a height of each of the unit structures may be determined according to the fourth variable.

An embodiment of the inventive concept provides a light source including a substrate, a light emitting layer provided on the substrate and configured to emit light, a plurality of unit structures provided on the light emitting layer, a barrier layer covering the unit structures, and a planarization layer covering the unit structures and the barrier layer, wherein the unit structures are arranged along a radial direction and a tangential direction to form an effective refractive index controlling pattern. The effective refractive index controlling pattern may be configured to control the effective refractive index through a first variable defined by a width of each of the unit structures, a second variable defined as a period in which the unit structures are arranged in the tangential direction, a third variable defined as a period in which the unit structures adjacent in the radial direction are arranged, and a fourth variable defined as a difference between a refractive index of the unit structures and a refractive index of a material surrounding the unit structures. The first variable may be smaller than a central wavelength of the light emitted from the light emitting layer. The effective refractive index controlling pattern may have rotational symmetry.

In an embodiment, the unit structures may include a material having a lower refractive index or the same as that of the planarization layer.

In an embodiment, each of the unit structures may have a cavity structure including a gas.

In an embodiment, the refractive index of the barrier layer may be greater than or equal to a refractive index of the unit structures, and may be smaller than or equal to a refractive index of the planarization layer.

In an embodiment, a height of each of the unit structures may have a size greater than or equal to a threshold value determined according to the following [Equation 1].

Δn×t_{c}=2π×λ [Equation 1]

Δn is the fourth variable, t_{c} is the threshold value, and λ is the central wavelength of the light emitted from the light emitting layer.

In an embodiment, the light source may further include a semiconductor layer between the light emitting layer and the unit structures, wherein the substrate and the semiconductor layer each may include a doped semiconductor material, wherein the light emitting layer may include a semiconductor material having at least one of a quantum well structure, a quantum wire structure, or a quantum dot structure.

In an embodiment, the light emitting layer may include a color conversion material causing fluorescence or phosphorescence.

An embodiment of the inventive concept provides a light source including a substrate, a light emitting layer provided on the substrate and configured to emit light, and a plurality of lenses provided on the light emitting layer. The lenses may be disposed repeatedly and are arranged to fill a plane. Each of the lenses may have an effective refractive index controlling pattern including a plurality of unit structures arranged along a radial direction and a tangential direction. The effective refractive index controlling pattern may be configured to control the effective refractive index through a first variable defined by a width of each of the unit structures, a second variable defined as a period in which the unit structures are arranged in the tangential direction, a third variable defined as a period in which the unit structures adjacent in the radial direction are arranged, and a fourth variable defined as a difference between a refractive index of the unit structures and a refractive index of a material surrounding the unit structures. The first variable may be smaller than a central wavelength of the light emitted from the light emitting layer. The effective refractive index controlling pattern may have rotational symmetry.

In an embodiment, each of the unit structures may have a cavity structure including a gas.

In an embodiment, in the effective refractive index controlling pattern of each of the lenses, a density of the unit structures monotonically may increase, monotonically decrease, or increase or decrease repeatedly along the radial direction.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view for explaining an effective refractive index controlling pattern according to embodiments of the inventive concept;

FIG. 2 is an enlarged view for explaining an effective refractive index controlling pattern according to embodiments of the inventive concept, and corresponds to part A of FIG. 1;

FIG. 3 is an enlarged view for explaining an effective refractive index controlling pattern according to embodiments of the inventive concept, and corresponds to part B of FIG. 2;

FIGS. 4 to 7 are cross-sectional views for explaining a light source including a lens according to embodiments of the inventive concept, and respectively correspond to a cross-section taken along line I-I′ in FIG. 2;

FIG. 8A is a cross-sectional view for explaining a light source including an effective refractive index controlling pattern according to embodiments of the inventive concept, and corresponds to a cross-sectional view taken along line I-I′ in FIG. 2;

FIG. 8B is an enlarged photograph for explaining a light source including an effective refractive index controlling pattern according to embodiments of the inventive concept, and corresponds to part C of FIG. 8A;

FIGS. 8C and 8D are cross-sectional views for explaining a method of manufacturing a light source including an effective refractive index controlling pattern according to embodiments of the inventive concept, and correspond to a cross-section taken along line I-I′ in FIG. 2;

FIG. 9 is a graph for explaining an effective refractive index according to a radial distance of an effective refractive index controlling pattern according to embodiments of the inventive concept;

FIG. 10 is a simulation result for explaining a relationship between a profile of a lens and an electric field emission form according to embodiments of the inventive concept;

FIGS. 11A and 11B are plan views illustrating a light source including an effective refractive index controlling pattern according to embodiments of the inventive concept;

FIGS. 12A to 12D and 13A to 13D are cross-sectional views for explaining a light source including an effective refractive index controlling pattern according to embodiments of the inventive concept; and

FIGS. 14A to 14C are graphs for explaining an effective refractive index profile of a lens according to embodiments of the inventive concept.

### DETAILED DESCRIPTION

In order to fully understand the configuration and effects of the inventive concept, preferred embodiments of the inventive concept will be described in detail with reference to the accompanying drawings.

The inventive concept is not limited to the embodiments disclosed below, but may be implemented in various forms, and various modifications and changes may be added. However, it is provided to completely disclose the technical idea of the inventive concept through the description of the present embodiments, and to fully inform a person of ordinary skill in the art to which the inventive concept belongs. In the accompanying drawings, for convenience of description, the ratio of each component may be exaggerated or reduced.

The terms used in this specification are for describing embodiments and are not intended to limit the inventive concept. In addition, terms used in the present specification may be interpreted as meanings commonly known to those of ordinary skill in the art, unless otherwise defined.

In this specification, the singular form also includes the plural form unless specifically stated in the phrase. As used in the specification, in relation to ‘comprises’ and/or ‘comprising’, the mentioned elements, steps, operations and/or elements do not exclude the presence or addition of one or more other elements, steps, operations and/or elements.

In this specification, terms such as first and second are used to describe various areas, directions, shapes, etc., but these areas, directions, and shapes should not be limited by these terms. These terms are only used to distinguish one area, direction, or shape from another area, direction, or shape. Accordingly, a portion referred to as a first portion in one embodiment may be referred to as a second portion in another embodiment. The embodiments described and illustrated herein also include complementary embodiments thereof. Like reference numerals refer to like elements throughout the specification.

Hereinafter, a light source including an effective refractive index controlling pattern according to embodiments of the inventive concept will be described in detail with reference to the drawings.

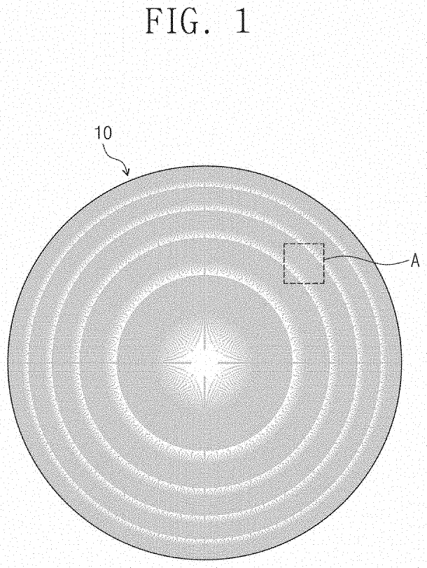

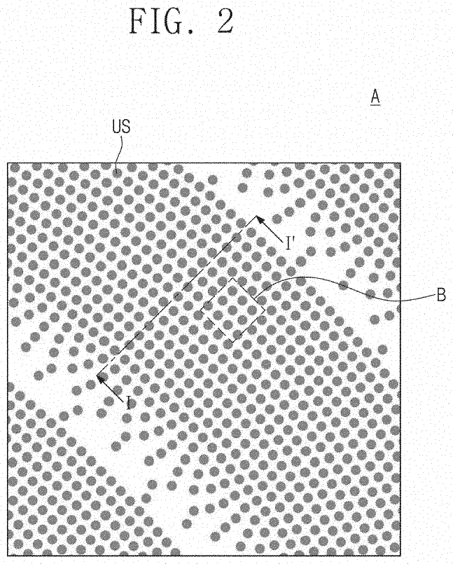

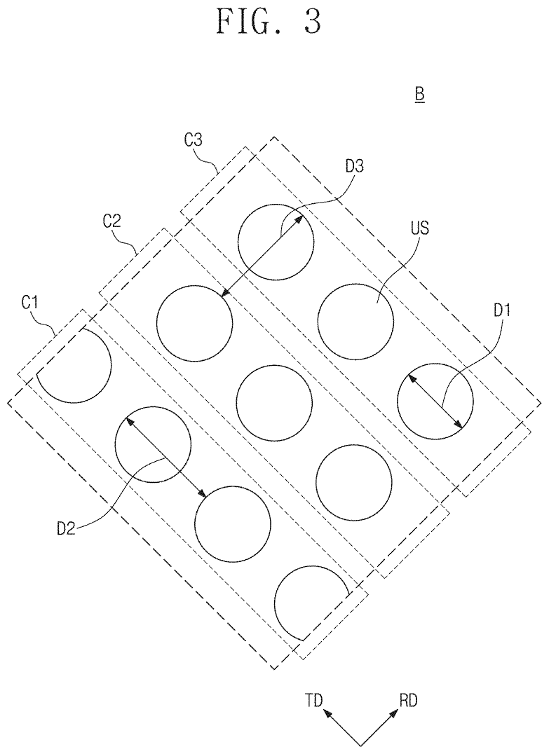

FIG. 1 is a plan view for explaining an effective refractive index controlling pattern according to embodiments of the inventive concept. FIG. 2 is an enlarged view for explaining an effective refractive index controlling pattern according to embodiments of the inventive concept, and corresponds to part A of FIG. 1. Part A is a part having a horizontal length and a vertical length of about 10 μm. FIG. 3 is an enlarged view for explaining an effective refractive index controlling pattern according to embodiments of the inventive concept, and corresponds to part B of FIG. 2.

Referring to FIGS. 1 to 3, a lens 10 having an effective refractive index controlling pattern may be provided. The lens 10 may have, for example, a circular shape.

The effective refractive index controlling pattern of the lens 10 may be formed of a plurality of unit structures US. The unit structures US may have, for example, a cylindrical shape. The volume and the area of the upper surface of each of the unit structures US may be substantially the same, for example, but the inventive concept is not limited thereto. The unit structures US may be arranged along the radial direction RD and the tangential direction TD. The unit structures US may be spaced apart from each other in a radial direction RD and a tangential direction TD. The effective refractive index controlling pattern including the unit structures US may have rotational symmetry. Specifically, the effective refractive index controlling pattern may overlap itself when rotated at an angle other than 360 degrees with respect to an axis passing through the center of the lens 10.

The density of the unit structures US in the effective refractive index controlling pattern of the lens 10 may not be constant. The density of the unit structures US may change in the radial direction RD. For example, one area of the lens 10 may be relatively sparse, and the other region of the lens 10 may be relatively dense. The density of the unit structures US may, for example, monotonically increase, monotonically decrease, or periodically and repeatedly increase or decrease from the center of the lens 10 in the radial direction RD. A period in which the increase/decrease in the density of the unit structures US is repeated may not be constant Likewise, ‘periodically changing’ hereinafter is not limited to changing with a constant period. For example, a period in which the increase/decrease in the density of the unit structures US is repeated may decrease from the center of the lens 10 in the radial direction RD.

The unit structures US may be provided in, for example, the first to third areas C1, C2, and, C3. The first to third areas C1, C2, and, C3 may be ring-shaped areas having different radii. In one ring shape, the unit structures US may be arranged at a constant period. For example, the density of the unit structures US may increase from the first area Cl to the third area C3.

The effective refractive index controlling pattern of the lens 10 may control the effective refractive index of the lens 10 through a first variable D1 defined by the width (or diameter) of each of the unit structures US, a second variable D2 defined as a period in which the unit structures US having the same distance from the center of the lens 10 are arranged in the tangential direction TD, and a third variable D3 defined as a period in which unit structures US adjacent in the radial direction RD are arranged.

In addition, the effective refractive index of the lens 10 may be controlled by a fourth variable Δn defined as a difference between the refractive index of the unit structures US and the refractive index of a background material surrounding the unit structures US. As the fourth variable Δn increases, focusing efficiency may be higher, and accordingly, a lens having a thinner thickness may obtain substantially the same directivity as other curved lenses.

For example, the first variable D1 may be substantially the same in each of the unit structures US. However, the inventive concept is not limited thereto, and the first variable D1 may increase, decrease, or change periodically as it moves away from the center of the lens 10. A period in which the increase/decrease in the first variable D1 is repeated may not be constant.

The first variable D1 may be smaller than a central wavelength of a light source including a lens having an effective refractive index controlling pattern.

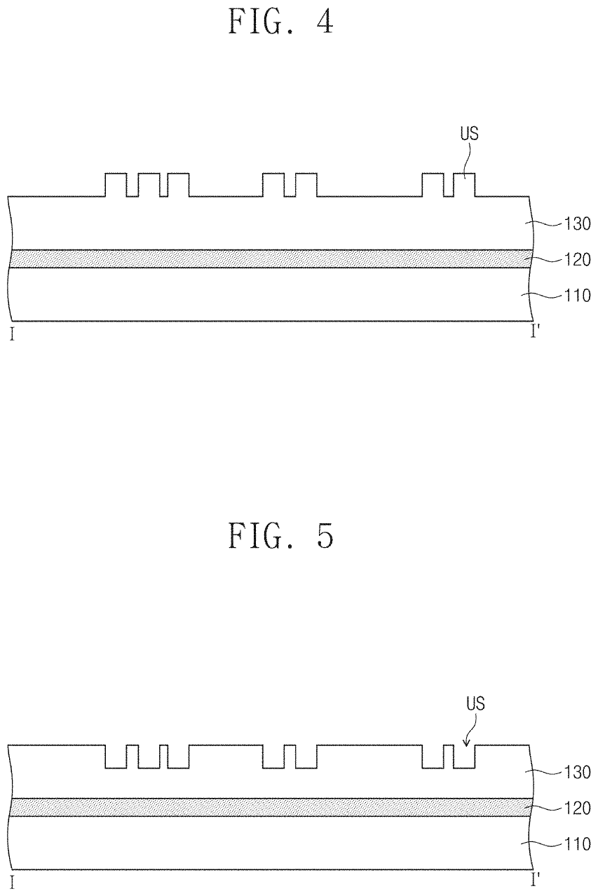

For example, in the case of a light source emitting light having a central wavelength of about 450 nm, the first variable D1 may be about 450 nm or less (preferably about 350 nm or less). As the first variable D1 is smaller, the characteristics of the plane wave may not be disturbed, and the effective refractive index may be efficiently controlled without changing the material. A light source including a lens having an effective refractive index controlling pattern will be described below in detail with reference to FIG. 4.

For example, the second variable D2 may decrease from the first area C1 to the third area C3. However, the inventive concept is not limited thereto, and the second variable D2 may be constant throughout the lens 10, and may increase, decrease, or change periodically as it moves away from the center of the lens 10. A period in which the increase/decrease in the second variable D2 is repeated may not be constant.

For example, the third variable D3 may be constantly maintained from the first area C1 to the third area C3. However, the inventive concept is not limited thereto, and the third variable D3 may increase, decrease, or change periodically as it moves away from the center of the lens 10. As the third variable D3 is smaller (i.e., the difference from the first variable D1 is smaller), the effective refractive index profile of the lens 10 may be more precise. The third variable D3 may be, for example, smaller than a central wavelength of a light source including a lens having an effective refractive index controlling pattern.

Embodiments of the inventive concept may control the effective refractive index profile of the lens 10 by constantly maintaining or changing at least one of the first to third variables D1, D2, and D3.

For example, the lens 10 according to the embodiments of the inventive concept may obtain a vertical directivity in which light is emitted around a direction perpendicular to the upper surface of the lens 10 according to an effective refractive index profile, and obtain horizontal directivity in which light is emitted with a constant inclination with respect to the upper surface of the lens 10.

FIGS. 4 to 7 are cross-sectional views for explaining a light source including a lens according to embodiments of the inventive concept, and respectively correspond to a cross-section taken along line I-I′ in FIG. 2. For convenience of description, descriptions of contents overlapping with those described with reference to the preceding drawings will be omitted. Hereinafter, the effective refractive index controlling pattern may be understood as the lens described with reference to FIGS. 1 to 3.

Referring to FIG. 4, a light source including an effective refractive index controlling pattern may include a substrate 110, a light emitting layer 120, and a semiconductor layer 130. The semiconductor layer 130 may be provided on the substrate 110, and the light emitting layer 120 may be provided between the substrate 110 and the semiconductor layer 130.

The substrate 110 and the semiconductor layer 130 may each include a doped semiconductor material. Each of the substrate 110 and the semiconductor layer 130 may include, for example, doped GaN, more specifically, p-type GaN doped with magnesium (Mg). The light emitting layer 120 may include a semiconductor material having at least one of a quantum well structure, a quantum wire structure, or a quantum dot structure. The light emitting layer 120 may include, for example, InGaN or AlGaN.

The unit structures US may be provided on the semiconductor layer 130. The unit structures US may be electrically connected to the light emitting layer 120. The unit structures US may be portions convexly protruding from the upper surface of the semiconductor layer 130. The unit structures US may be formed by patterning the semiconductor layer 130. The unit structures US may constitute a lens having an effective refractive index controlling pattern.

Referring to FIG. 5, the unit structures US may be portions concavely recessed from the upper surface of the semiconductor layer 130. For example, the unit structures US may have a cavity structure including a gas.

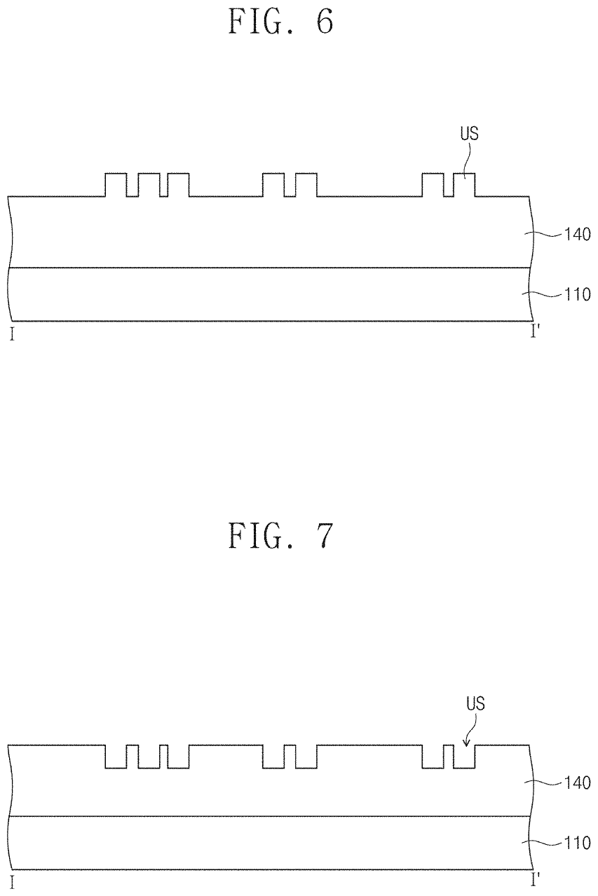

Referring to FIGS. 6 and 7, a phosphor layer 140 may be provided on the substrate 110 instead of the light emitting layer 120 and the semiconductor layer 130 of FIGS. 4 and 5. The phosphor layer 140 may include a color conversion material causing fluorescence or phosphorescence. The phosphor layer 140 may, for example, include Yttrium Aluminum Garnet (YAG) doped with Nd, Er or Cr, β-SiAlON doped with Ca or Eu, K₂SiF₆ (KSF) doped with Mn or the like, or a quantum dot phosphor using CdSe, InN, or the like.

Referring to FIG. 6, the unit structures US may be portions convexly protruding from the upper surface of the phosphor layer 140. Referring to FIG. 7, the unit structures US may be portions concavely recessed from the upper surface of the phosphor layer 140, and may have a cavity structure including gas. The unit structures US may be formed by patterning the phosphor layer 140.

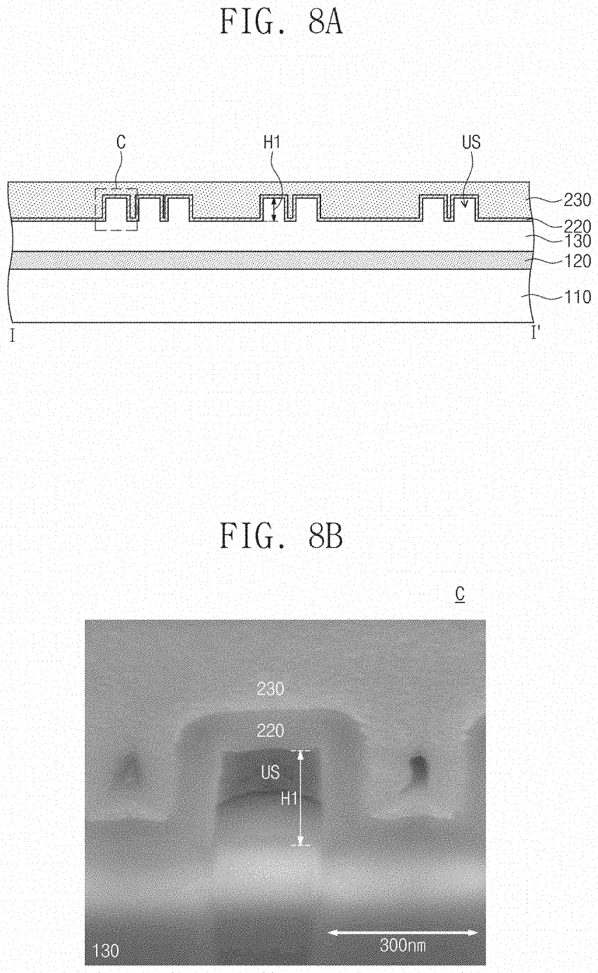

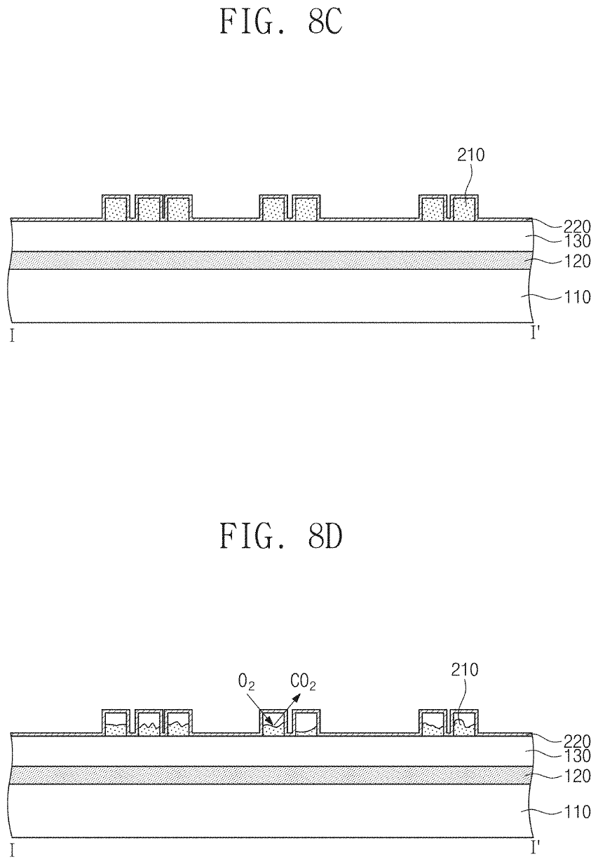

FIG. 8A is a cross-sectional view for explaining a light source including an effective refractive index controlling pattern according to embodiments of the inventive concept, and corresponds to a cross-sectional view taken along line I-I′ in FIG. 2. FIG. 8B is an enlarged photograph for explaining a light source including an effective refractive index controlling pattern according to embodiments of the inventive concept, and corresponds to part C of FIG. 8A. For convenience of description, descriptions of contents overlapping with those described with reference to the preceding drawings will be omitted.

Referring to FIGS. 8A and 8B, a light source including an effective refractive index controlling pattern may include a substrate 110, a light emitting layer 120, a semiconductor layer 130, unit structures US on the semiconductor layer 130, a barrier layer 220 covering the unit structures US, and a planarization layer 230 covering the barrier layer 220. The unit structures US may be arranged along the radial direction RD (see FIG. 3) and the tangential direction TD (see FIG. 3) to form an effective refractive index controlling pattern. A planarization layer 230 may be provided on the unit structures US, and a barrier layer 220 may be provided between the unit structures US and the planarization layer 230. The barrier layer 220 may cover the unit structures US and extend to the upper surface of the semiconductor layer 130. However, unlike illustrated, the barrier layer 220 may cover only the unit structures US and may not extend to the upper surface of the semiconductor layer 130.

The unit structures US may include a material having a lower refractive index or the same as that of the planarization layer 230. As an example, the unit structures US may have a cavity structure including a gas. The width of each of the unit structures US may be the first variable D1 described with reference to FIG. 3. That is, the width of each of the unit structures US may be smaller than the central wavelength of the light source including the effective refractive index controlling pattern. For example, the width of the unit structures US may decrease as the distance from the substrate 110 increases.

The height H1 of each of the unit structures US may be required to have a size greater than or equal to the threshold value t_{c} for a phase change in the range of 0 to 2π. As the above-described fourth variable Δn increases, the threshold value t_{c} may decrease. That is, as the difference between the refractive index of the unit structures US and the refractive index of the background material surrounding the unit structures US increases, a thinner and flatter lens may be implemented. The threshold value t_{c} may be determined by the following [Equation 1].

Δn×t_{c}=2π×λ [Equation 1]

In this case, Δn is the fourth variable, t_{c} is the threshold value of the height H1 of each of the unit structures US, and λ is the center wavelength of the light source. More specifically, λ may be defined as a central wavelength or a peak wavelength among wavelength bands of light emitted from a light source. The center wavelength of the light source or the center wavelength of light described elsewhere in this specification may likewise be defined.

The barrier layer 220 may be a porous thin film that conformally covers the upper surfaces of the unit structures US and the semiconductor layer 130. The refractive index of the barrier layer 220 may be greater than or equal to the refractive index of the unit structures US, and may be smaller than or equal to the refractive index of the planarization layer 230. For example, the barrier layer 220 may include a plurality of layers having different refractive indices. The barrier layer 220 may include, for example, any one of SiO₂, Al₂O₃, TiO₂, ZrO₂, Y₂O₃, CuO, Cu₂O, Ta₂O₅, Si₃N₄₋ₓ, HfO₂, In₂O₃₋ₓ, Sn₃O₄, ZnO, or a compound of two or more. However, this is merely exemplary, and the inventive concept is not limited thereto, and the barrier layer 220 may include various oxide or nitride-based compounds.

The upper surface of the planarization layer 230 may be parallel to the upper surface of the substrate 110 and the upper surface of the light emitting layer 120, and may be a substantially flat surface without convex and/or concave portions. The planarization layer 230 may include, for example, any one or a compound of two or more of SiO₂, TiO₂, HfO₂, Al₂O₃, Si₃N₄₋ₓ, In₂O₃₋ₓ, Sn₃O₄, and ZnO. However, this is merely exemplary, and the inventive concept is not limited thereto, and the planarization layer 230 may include various oxide or nitride-based compounds. The planarization layer 230 may protect the unit structures US from external contamination and physical damage, and may reduce light loss due to surface reflection.

FIGS. 8C and 8D are cross-sectional views for explaining a method of manufacturing a light source including an effective refractive index controlling pattern according to embodiments of the inventive concept, and correspond to a cross-section taken along line I-I′ in FIG. 2.

Referring to FIG. 8C, a sacrificial pattern 210 may be formed on the semiconductor layer 130. The sacrificial pattern 210 may be formed by patterning the sacrificial layer formed on the semiconductor layer 130. The sacrificial pattern 210 may include an organic material.

Thereafter, a barrier layer 220 that conformally covers the sacrificial pattern 210 and the semiconductor layer 130 may be formed. The barrier layer 220 may be formed by a physical vapor deposition (PVD) method, an atomic layer deposition (ALD) method, wet synthesis, and an oxidation process (metal deposition and oxidation) after forming a metal thin film. When the barrier layer 220 is formed by a physical vapor deposition method such as sputtering, it may be formed at a low temperature of 200° C. or less, and pure metal, nitride, or oxide may be used as a precursor for physical vapor deposition.

Referring to FIG. 8D, the sacrificial pattern 210 may be removed by injecting an oxidation agent through the barrier layer 220 which is a porous thin film. For example, the carbon component of the sacrificial pattern 210 may react with oxygen (O₂) injected through the barrier layer 220 and may exit the barrier layer 220 in the form of carbon dioxide (CO₂).

Referring to FIGS. 8A and 8B again, when the removal of the sacrificial pattern 210 is completed, a planarization layer 230 covering the barrier layer 220 may be formed. The planarization layer 230 may be deposited by a method such as PVD, ALD, or the like, and after deposition, a planarization process may be performed on the upper surface.

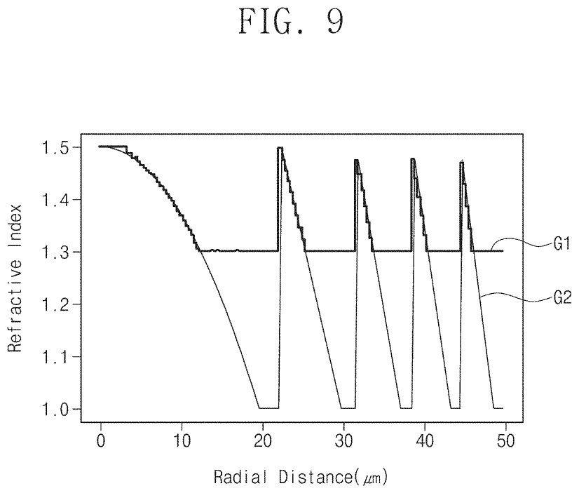

FIG. 9 is a graph for explaining an effective refractive index according to a radial distance of an effective refractive index controlling pattern according to embodiments of the inventive concept. The horizontal axis represents the radial distance from the center of the lens, and the unit is pm. The vertical axis represents the effective refractive index.

Referring to FIG. 9, a first curve G1 and a second curve G2 each represent an effective refractive index profile of an effective refractive index controlling pattern according to an embodiment of the inventive concept.

Again, referring to FIGS. 1 to 3, the first curve G1 is a case where the fourth variable Δn is about 0.5, and the second curve G1 is a case where the fourth variable Δn is about 1.5. The lens 10 having an effective refractive index controlling pattern according to an embodiment of the inventive concept may simulate a curvature function of a curved lens by adjusting the thickness of the effective refractive index controlling pattern, the first to third variables D1, D2, and D3, and the fourth variable Δn.

As the first to third variables D1, D2, and D3 decrease, as the fourth variable Δn increases, and as the thickness of the effective refractive index controlling pattern increases, resemblance with an ideal curved lens may be improved. Accordingly, the light source including the lens 10 having an effective refractive index controlling pattern according to an embodiment of the inventive concept may exhibit high and even transmittance according to an incident angle of light generated from the light source, and may improve light efficiency.

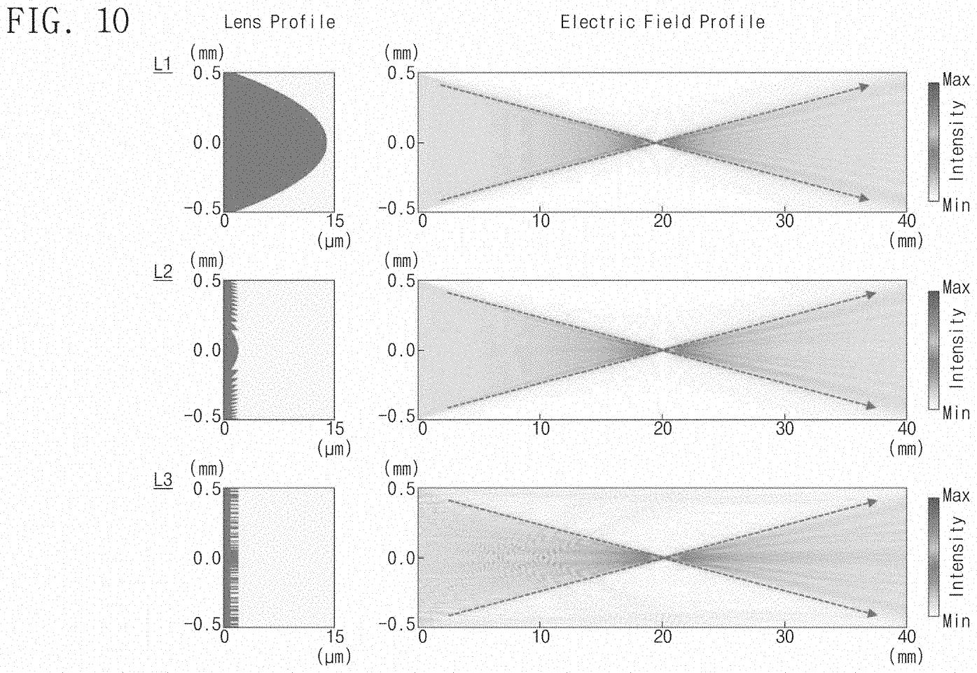

FIG. 10 is a simulation result for explaining a relationship between a profile of a lens and an electric field emission form according to embodiments of the inventive concept.

Referring to the graphs shown on the left of FIG. 10, the first lens Ll is a general curved lens made of a material having a refractive index of about 1.5, the second lens L2 is a Fresnel lens having substantially the same function as the curved lens, and the third lens L3 is a lens having an effective refractive index controlling pattern according to embodiments of the inventive concept. In each of the graphs shown on the left of FIG. 10, the horizontal axis is in μm, and the vertical axis is in mm. Like the second lens L2, the third lens L3 may have a thickness smaller than that of the first lens L1.

Referring to the graphs shown on the right side of FIG. 10, it may be seen that the electric field emission shape of the first to third lenses L1, L2, and L3 is substantially the same. That is, a lens having an effective refractive index controlling pattern according to embodiments of the inventive concept may exhibit substantially the same directivity as a general curved lens and a Fresnel lens.

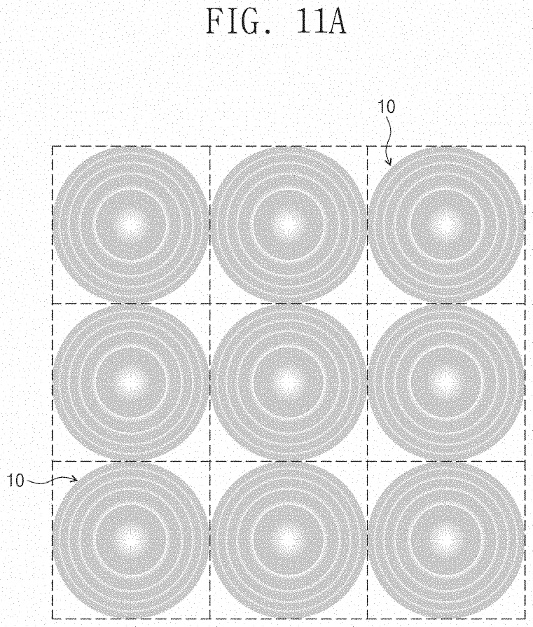

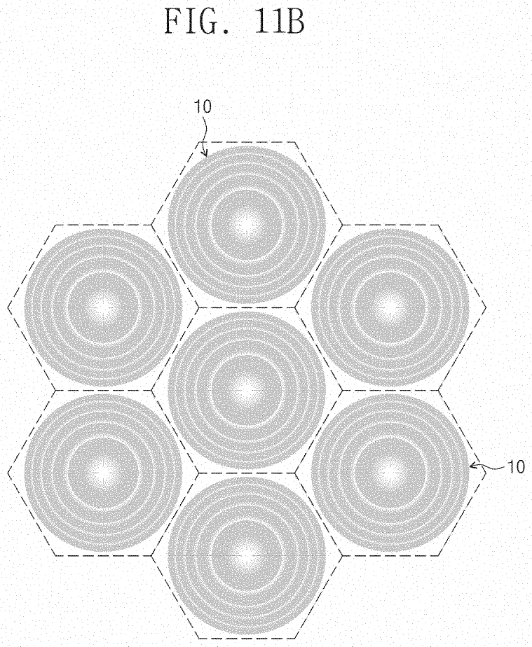

FIGS. 11A and 11B are plan views illustrating a light source including an effective refractive index controlling pattern according to embodiments of the inventive concept.

The plurality of lenses 10 as shown in FIG. 1 may be provided on the substrate 110 as shown in FIGS. 4 to 7 and 8A to 8D. Referring to FIG. 11A, the lenses 10 may be arranged side by side in a horizontal direction and a vertical direction. Referring to FIG. 11B, lenses 10 each inscribed in virtual regular hexagons may be arranged in a honeycomb pattern. However, the inventive concept is not limited thereto, and the plurality of lenses 10 may be arranged to fill the plane in various ways. For example, the polygon constituting the shape of the honeycomb pattern is not limited to a regular hexagon and may have various shapes that are repeatedly arranged to fill a plane.

When an effective refractive index controlling pattern is provided on a surface light source, by arranging the plurality of lenses 10, it is possible to prevent deterioration of light efficiency and focusing speed.

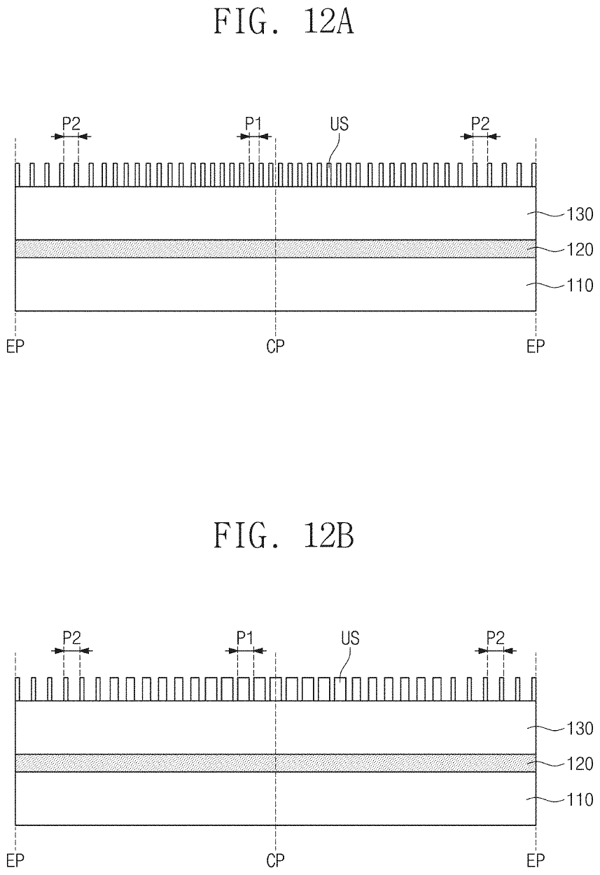

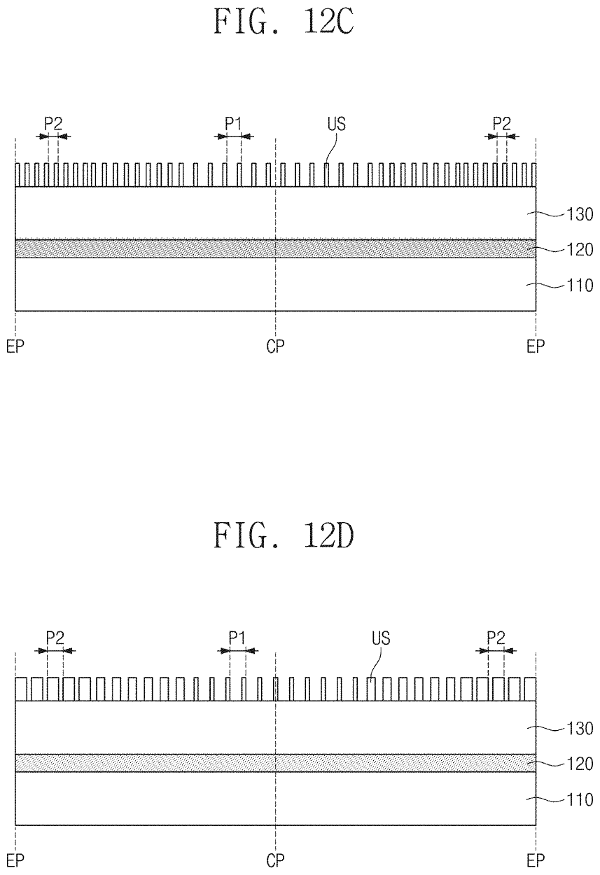

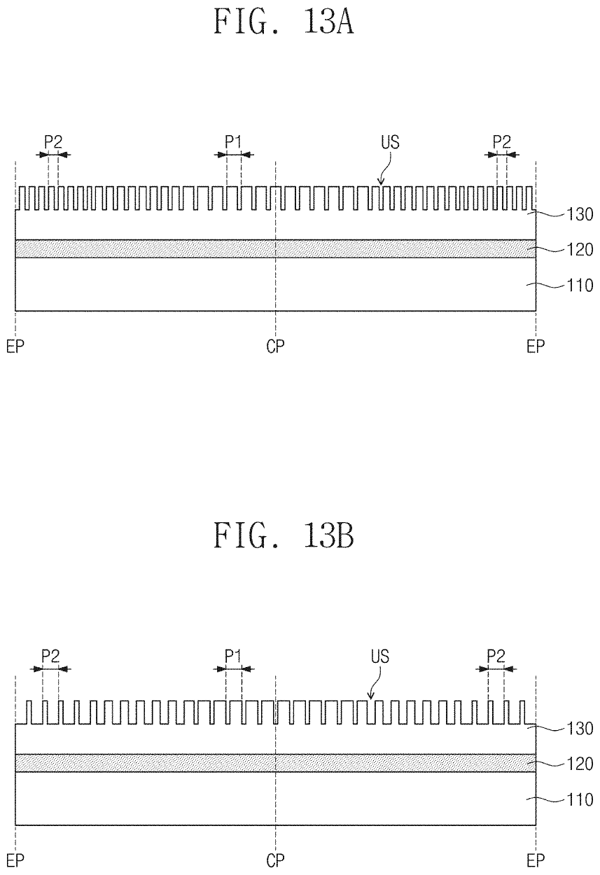

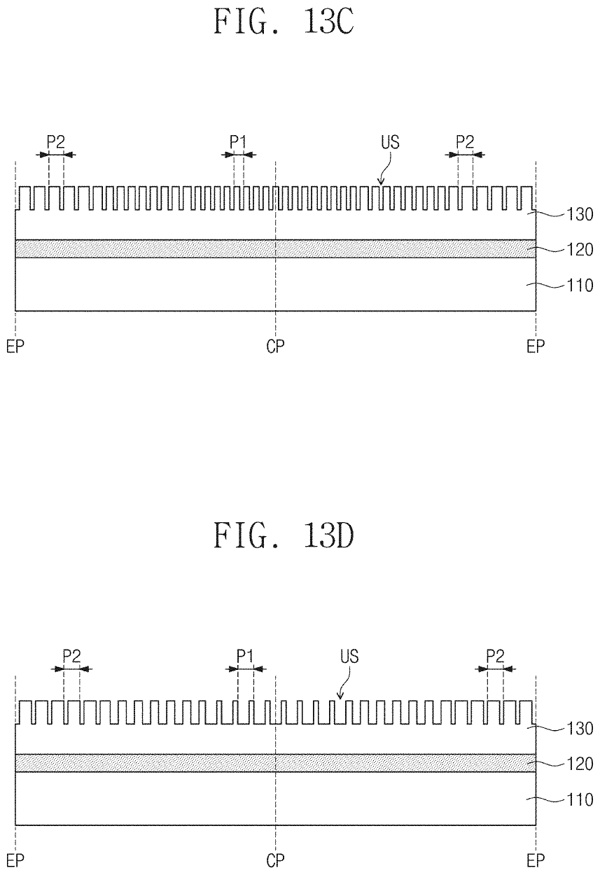

FIGS. 12A to 12D and 13A to 13D are cross-sectional views for explaining a light source including an effective refractive index controlling pattern according to embodiments of the inventive concept. For convenience of description, descriptions of contents overlapping with those described with reference to the preceding drawings will be omitted.

Referring to FIGS. 12A to 12D, the unit structures US may convexly protrude from the upper surface of the semiconductor layer 130. The unit structures US may be arranged at a first pitch P1 in the center portion CP, and may be arranged at a second pitch P2 in the edge portion EP. The first pitch P1 and the second pitch P2 may each be the third variable D3 described with reference to FIG. 3. In a cross-sectional view, the unit structures US may be symmetrically arranged with respect to the center portion CP. Although not shown, in a plan view, the effective refractive index controlling pattern including the unit structures US may have rotational symmetry with respect to the center portion CP.

Referring to FIG. 12A, the first pitch P1 may be smaller than the second pitch P2. For example, the pitch at which the unit structures US are arranged may gradually decrease from the edge portion EP to the center portion CP. Accordingly, the effective refractive index controlling pattern including the unit structures US may have a high effective refractive index in the center portion CP and have a low effective refractive index in the edge portion EP.

Referring to FIG. 12B, the first pitch P1 and the second pitch P2 may be substantially the same. However, the width (or diameter) of the unit structures US of the center portion CP may be greater than the width (or diameter) of the unit structures US of the edge portion EP. For example, the width (or diameter) of the unit structures US may gradually increase from the edge portion EP to the center portion CP. Accordingly, the effective refractive index controlling pattern including the unit structures US may have a high effective refractive index in the center portion CP and have a low effective refractive index in the edge portion EP.

Referring to FIG. 12C, the first pitch P1 may be greater than the second pitch P2. For example, the pitch at which the unit structures US are arranged may gradually increase from the edge portion EP to the center portion CP. Accordingly, the effective refractive index controlling pattern including the unit structures US may have a low effective refractive index in the center portion CP and have a high effective refractive index in the edge portion EP.

Referring to FIG. 12D, the first pitch P1 and the second pitch P2 may be substantially the same. However, the width (or diameter) of the unit structures US of the center portion CP may be smaller than the width (or diameter) of the unit structures US of the edge portion EP. For example, the width (or diameter) of the unit structures US may gradually decrease from the edge portion EP to the center portion CP. Accordingly, the effective refractive index controlling pattern including the unit structures US may have a low effective refractive index in the center portion CP and have a high effective refractive index in the edge portion EP.

Referring to FIGS. 13A to 13D, the unit structures US may have a cavity structure concavely recessed from the upper surface of the semiconductor layer 130. The unit structures US may be arranged at a first pitch P1 in the center portion CP and may be arranged at a second pitch P2 in the edge portion EP.

Referring to FIG. 13A, the first pitch P1 may be greater than the second pitch P2. For example, the pitch at which the unit structures US are arranged may gradually increase from the edge portion EP to the center portion CP. Accordingly, the effective refractive index controlling pattern including the unit structures US may have a high effective refractive index in the center portion CP and have a low effective refractive index in the edge portion EP.

Referring to FIG. 13B, the first pitch P1 and the second pitch P2 may be substantially the same. However, the width (or diameter) of the unit structures US of the center portion CP may be smaller than the width (or diameter) of the unit structures US of the edge portion EP. For example, the width (or diameter) of the unit structures US may gradually decrease from the edge portion EP to the center portion CP. Accordingly, the effective refractive index controlling pattern including the unit structures US may have a high effective refractive index in the center portion CP and have a low effective refractive index in the edge portion EP.

Referring to FIG. 13C, the first pitch P1 may be smaller than the second pitch P2. For example, the pitch at which the unit structures US are arranged may gradually decrease from the edge portion EP to the center portion CP. Accordingly, the effective refractive index controlling pattern including the unit structures US may have a low effective refractive index in the center portion CP and have a high effective refractive index in the edge portion EP.

Referring to FIG. 13D, the first pitch P1 and the second pitch P2 may be substantially the same. However, the width (or diameter) of the unit structures US of the center portion CP may be greater than the width (or diameter) of the unit structures US of the edge portion EP. For example, the width (or diameter) of the unit structures US may gradually increase from the edge portion EP to the center portion CP. Accordingly, the effective refractive index controlling pattern including the unit structures US may have a low effective refractive index in the center portion CP and have a high effective refractive index in the edge portion EP.

In summary, the effective refractive index controlling pattern according to FIGS. 12A, 12B, 13A and 13B may have a high effective refractive index in the center portion CP and have a low effective refractive index in the edge portion EP. On the other hand, the effective refractive index controlling pattern according to FIGS. 12C, 12D, 13C and 13D may have a low effective refractive index in the center portion CP and have a high effective refractive index in the edge portion EP. That is, the effective refractive index controlling pattern according to embodiments of the inventive concept may exhibit substantially the same directivity as a convex lens or a concave lens.

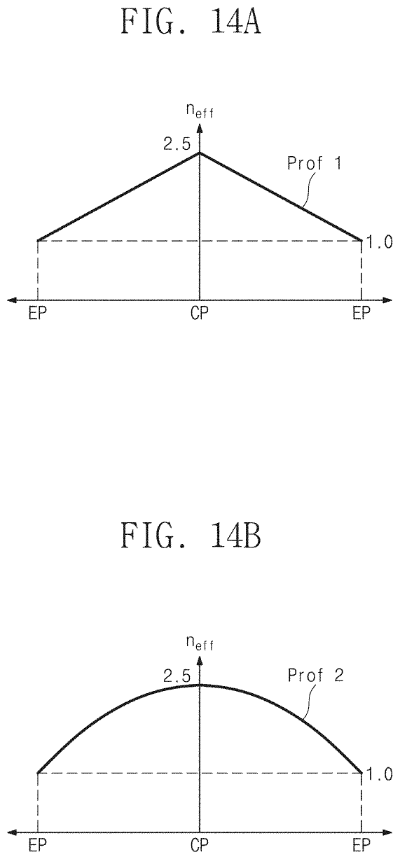

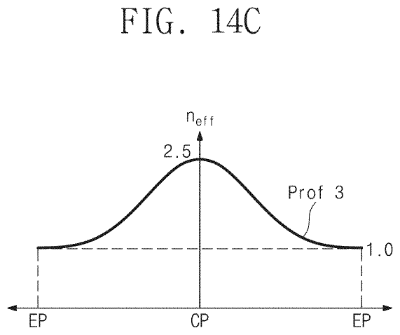

FIGS. 14A to 14C are graphs for explaining an effective refractive index profile of a lens according to embodiments of the inventive concept. 14A to 14C are for explaining that various effective refractive index profiles may be implemented in addition to the effective refractive index profile shown in FIG. 9 according to embodiments of the inventive concept.

Referring to FIG. 14A, in the lens having the first profile Prof1, the effective refractive index may linearly decrease from the center portion CP to the edge portion EP.

Referring to FIG. 14B, in the lens having the second profile Prof2, the effective refractive index may decrease in a curved shape such as a quadratic function from the center portion CP to the edge portion EP. The slope of the second profile Prof2 may increase from the center portion CP to the edge portion EP.

Referring to FIG. 14C, the lens having the third profile Prof3 may have an effective refractive index in the form of a Gaussian function averaging the center portion CP. The effective refractive index of the lens having the third profile Prof3 may decrease from the center portion CP toward the edge portion EP, but the slope of the third profile Prof3 may increase from the center portion CP to the edge portion EP and then decrease after the inflection point.

For example, the effective refractive index profiles shown in FIGS. 14A to 14C may correspond to the effective refractive index controlling patterns according to FIGS. 12A, 12B, 13A and 13B. However, the effective refractive index profiles shown in FIGS. 14A to 14C are exemplary only, and the inventive concept is not limited thereto. The effective refractive index profile of the lens according to the embodiments of the inventive concept may be in a form in which the effective refractive index profile shown in FIGS. 14A to 14C is vertically inverted, or may be in the form of a discontinuous curve or a curve including non-differentiable points.

The lens according to an embodiment of the inventive concept may control the effective refractive index through variables of the effective refractive index controlling pattern, and thus the directivity may be adjusted.

In addition, the light source according to an embodiment of the inventive concept comprises one or more lenses having an effective refractive index controlling pattern, so that the transmittance and light efficiency according to the angle of incidence may be improved by minimizing surface reflection for all emission angles of the light generated from the light source and allowing emission to the outside.

Although the embodiments of the inventive concept have been described, it is understood that the inventive concept should not be limited to these embodiments but various changes and modifications may be made by one ordinary skilled in the art within the spirit and scope of the inventive concept as hereinafter claimed.

What is claimed is:

1. A light source comprising:
a substrate;
a light emitting layer provided on the substrate and configured to emit light; and
a plurality of unit structures provided on the light emitting layer,
wherein the unit structures are arranged along a radial direction and a tangential direction to form an effective refractive index controlling pattern,
wherein the effective refractive index controlling pattern is configured to control the effective refractive index through a first variable defined by a width of each of the unit structures, a second variable defined as a period in which the unit structures are arranged in the tangential direction, a third variable defined as a period in which the unit structures adjacent in the radial direction are arranged, and a fourth variable defined as a difference between a refractive index of the unit structures and a refractive index of a material surrounding the unit structures,
wherein the first variable is smaller than a central wavelength of the light emitted from the light emitting layer,
wherein the effective refractive index controlling pattern has rotational symmetry.

2. The light source of claim 1, wherein a density of the unit structures changes in the radial direction.

3. The light source of claim 2, wherein the density of the unit structures monotonically increases, monotonically decreases, or increases or decreases repeatedly along the radial direction.

4. The light source of claim 1, wherein in the effective refractive index controlling pattern, the first variable is constant.

5. The light source of claim 4, wherein in the effective refractive index controlling pattern, the second variable increases along the radial direction.

6. The light source of claim 4, wherein in the effective refractive index controlling pattern, the second variable decreases along the radial direction.

7. The light source of claim 1, wherein in the effective refractive index controlling pattern, the third variable is smaller than the central wavelength of the light.

8. The light source of claim 7, wherein in the effective refractive index controlling pattern, the first variable decreases along the radial direction.

9. The light source of claim 7, wherein in the effective refractive index controlling pattern, the first variable increases along the radial direction.

10. The light source of claim 1, wherein a height of each of the unit structures is determined according to the fourth variable.

11. A light source comprising:
a substrate;
a light emitting layer provided on the substrate and configured to emit light;
a plurality of unit structures provided on the light emitting layer;
a barrier layer covering the unit structures; and
a planarization layer covering the unit structures and the barrier layer,
wherein the unit structures are arranged along a radial direction and a tangential direction to form an effective refractive index controlling pattern,
wherein the effective refractive index controlling pattern is configured to control the effective refractive index through a first variable defined by a width of each of the unit structures, a second variable defined as a period in which the unit structures are arranged in the tangential direction, a third variable defined as a period in which the unit structures adjacent in the radial direction are arranged, and a fourth variable defined as a difference between a refractive index of the unit structures and a refractive index of a material surrounding the unit structures,
wherein the first variable is smaller than a central wavelength of the light emitted from the light emitting layer,
wherein the effective refractive index controlling pattern has rotational symmetry.

12. The light source of claim 11, wherein the unit structures comprise a material having a lower refractive index or the same as that of the planarization layer.

13. The light source of claim 12, wherein each of the unit structures has a cavity structure including a gas.

14. The light source of claim 11, wherein the refractive index of the barrier layer is greater than or equal to a refractive index of the unit structures, and is smaller than or equal to a refractive index of the planarization layer.

15. The light source of claim 11, wherein a height of each of the unit structures has a size greater than or equal to a threshold value determined according to the following [Equation 1].
Δn×t_{c}=2π×λ [Equation 1]
Δn is the fourth variable, t_{c} is the threshold value, and λ is the central wavelength of the light emitted from the light emitting layer.

16. The light source of claim 11, further comprising a semiconductor layer between the light emitting layer and the unit structures,
wherein the substrate and the semiconductor layer each comprise a doped semiconductor material,
wherein the light emitting layer comprises a semiconductor material having at least one of a quantum well structure, a quantum wire structure, or a quantum dot structure.

17. The light source of claim 11, wherein the light emitting layer comprises a color conversion material causing fluorescence or phosphorescence.

18. A light source comprising:
a substrate;
a light emitting layer provided on the substrate and configured to emit light; and
a plurality of lenses provided on the light emitting layer,
wherein the lenses are disposed repeatedly and are arranged to fill a plane,
wherein the lenses each have an effective refractive index controlling pattern including a plurality of unit structures arranged along a radial direction and a tangential direction,
wherein the effective refractive index controlling pattern is configured to control the effective refractive index through a first variable defined by a width of each of the unit structures, a second variable defined as a period in which the unit structures are arranged in the tangential direction, a third variable defined as a period in which the unit structures adjacent in the radial direction are arranged, and a fourth variable defined as a difference between a refractive index of the unit structures and a refractive index of a material surrounding the unit structures,
wherein the first variable is smaller than a central wavelength of the light emitted from the light emitting layer,
wherein the effective refractive index controlling pattern has rotational symmetry.

19. The light source of claim 18, wherein each of the unit structures has a cavity structure including a gas.

20. The light source of claim 18, wherein in the effective refractive index controlling pattern of each of the lenses, a density of the unit structures monotonically increases, monotonically decreases, or increases or decreases repeatedly along the radial direction.
